(19) United States
(12) Patent Application Publication
(10) Pub. No.: US 2006/0003577 A1
(43) Pub. Date: Jan. 5, 2006

(54) Method of manufacturing a semiconductor device

(75) Inventor: Shuji Sone, Tama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies, Inc., Tsukuba-shi (JP)

(21) Appl. No.: 11/037,163

(22) Filed: Jan. 19, 2005

(30) Foreign Application Priority Data
Jul. 1, 2004 (JP) 2004-195381

(51) Int. Cl. H01L 21/4763

(52) U.S. Cl. 438/638; 438/644

(57) ABSTRACT

To effectively reduce the dielectric constant of an interlayer insulation film including a low dielectric constant film of a porous structure, and easily realize a practical application of a semiconductor device having an ultrafine and highly reliable Damascene wiring structure. A first interlayer insulation film including a porous first low dielectric constant film is formed on a lower layer wiring, and a first side wall metal is formed on a side wall of a via hole arranged in the first low dielectric constant film, and thereafter a first etching stopper layer is etched and the lower layer wiring is exposed. Then, a via plug is embedded into the via hole. In the same manner, after a second side wall metal is arranged on a side wall of a trench in a second interlayer insulation film including a porous second low dielectric constant film, a second etching stopper layer is etched, and an upper layer wiring that connects to the via plug is formed.

### BACKGROUND OF THE INVENTION

1. Field of the Invention

The present invention relates to a method of manufacturing a semiconductor device, more specifically, to a method of manufacturing a semiconductor device that has a multilayer wiring structure where a porous low dielectric constant film is used as an interlayer insulation film.

2. Description of Related Art

Miniaturization of elements that constitute semiconductor devices is most important for high performances of the semiconductor devices, and at present, technical developments are energetically proceeded toward the dimensional design standard from 65 nm to 45 nm. Further, in high performances of semiconductor devices having such a miniaturized structure as described above, for achieving low resistance of wirings for connecting elements and reduction of parasitic capacity of wirings, slot wirings formed by a so-called Damascene method, i.e., Damascene wirings have become indispensable, where a wiring material film of a copper (Cu) film or the like is accumulated on an interlayer insulation film on which slots are formed by miniature processing, and the wiring material film at other portions than slots into which the wiring material film is filled is removed by Chemical Mechanical Polishing (CMP).

In the formation of the above Damascene wirings, as a material for an interlayer insulation film, in the place of a silicon oxide film, an insulation film material of a so-called low dielectric constant film whose specific dielectric constant is lower is indispensable. In order to promote the low dielectric constant of the interlayer insulation film, making a low dielectric constant film porous is the most effective means. Herein, the low dielectric constant film means an insulation film of a silicon dioxide film whose specific dielectric constant is 3.9 or below.

However, in the case where a porous low dielectric constant film is concretely applied to manufacturing processes for Damascene wirings of a semiconductor device, it is anticipated that the following problems may occur, and solutions to them have been proposed. The first problem comes from that fact that the inclusion ratio of hallow holes in a low dielectric constant film will increase and the specific dielectric constant thereof will become small and the mechanical strength of an interlayer insulation film will decrease inevitably, and is that the decrease of the mechanical strength of the interlayer insulation film causes cracks owing to thermal stress, and as a result, short-circuit failures among Damascene wirings are likely to occur. Therefore, a technique to arrange a high Young's modulus insulation film as a side wall protection film onto side walls of a connection hole (via hole) or a wiring slot (trench) formed in an interlayer insulation film is proposed (for example, refer to Japanese Patent Application Laid-Open (JP-A) No. 2003-197742) Then, the second problem is that many hallow holes (pores) are exposed on side walls of the via hole and the trench in manufacturing processes, and water content, Cu of a wiring material film or, for example, tantalum nitride (TaN) to become a barrier layer thereof etc. gets into the interlayer insulation film through these pores, thereby causing an increase of specific dielectric constant and a decline of reliability of the interlayer insulation film, an increase of leak current among wirings, a connection failure at via portions, and so forth. Therefore, a technique to arrange a fine film quality inorganic insulation film (pore seal) as a side wall protection film onto side walls of the via hole or the trench is proposed (for example, refer to JP-A-2000-294634).

Hereinafter, the technique to manufacture Damascene wirings by forming a side wall protection film onto side walls of a via hole or a trench of an interlayer insulation film including a low dielectric constant film is explained by reference to FIGS. 10 and 11. FIGS. 10 and 11 are cross sectional views of elements in processes in the case of forming dual Damascene wirings by use of a pore seal disclosed in the JP-A-2000-294634.

As shown in FIG. 10A, on a lower layer wiring 101 consisting of a Cu film, a P—SiN film 102 as a plasma silicon nitride film, a first low dielectric constant film 103, a first P—SiO₂ film 104 as a plasma silicon oxide film, a second low dielectric constant film 105, and a second P—SiO₂ film 106 are laminated and formed. Thereafter, by use of known lithography technology and dry etching technology, a via opening 107 is formed in the second P—SiO₂ film 106 and the second low dielectric constant film 105, and the first P—SiO₂ film 104 is exposed.

Next, as shown in FIG. 10B, a resist mask 108 having a trench pattern is formed. Then, by reactive ion etching (RIE) with the resist mask 108 as an etching mask, first, by use of hydrofluoro carbon system gas, the exposed portions of the second P—SiO₂ film 106 and the first P—SiO₂ film 104 are etched and removed.

Next, as shown in FIG. 10C, with the second P—SiO₂ film 106 as an etching mask and the first P—SiO₂ film 104 as an etching stopper, by RIE using, for example, fluoro carbon system etching gas, the exposed second low dielectric constant film 105 is etched, and a via hole is formed in the first low dielectric constant film 103. In this RIE, the resist mask 108 is removed in prior, and does not work as an etching mask. Subsequently, with the first P—SiO₂ film 104 and the second P—SiO₂ film 106 as etching masks, the P—SiN film 102 exposed at the via hole is etched and removed, and the via hole is let go through to the surface of the lower layer wiring 101, thereby a via hole and a trench of a dual Damascene structure are formed.

Next, as shown in FIG. 10D, a third P—SiO₂ film (inorganic insulation film) 109 with a film thickness around 50 nm is coated over the entire surface by chemical vapor deposition (CVD). Thereafter, etch-back is carried out to remove the third P—SiO₂ film 109 on the surface of the lower layer wiring 101. In this process, as shown in FIG. 11A, the third P—SiO₂ film 109 is left as side walls of the insulation film, and covers the side walls of the first low dielectric constant film 103 and the second low dielectric constant film 105 as a side wall protection film 110. Herein, the side wall protection film 110 covers also the side walls of the first P—SiO₂ film 104 and the second P—SiO₂ film 106.

Next, the oxide layer of the surface of the lower layer wiring 101 is reduced and removed, and as shown in FIG. 11B, a barrier metal film 111 is formed on the entire surface by spatter (PVD) method, and a Cu film 112 is accumulated thereonto by a plating method or the like. Then, by the CMP method, the unnecessary barrier metal film 111 and Cu film 112 on the surface of the second P—SiO₂ film 106 are polished and removed, and as shown in FIG. 11C, an upper layer wiring 113 of a dual Damascene wiring structure that is to be electrically connected to the lower layer wiring 101 is formed. In this manner, a Damascene wiring having side wall protection films 110 on the side walls of the via hole and the trench of a dual Damascene structure arranged in the first low dielectric constant film 103 and the second low dielectric constant film 105 is completed.

### SUMMARY OF THE INVENTION

An object of the present invention is to realize a practical application of an ultrafine Damascene wiring structure wherein an increase in the effective dielectric constant of a wiring interlayer insulation film including a low dielectric constant film of a porous structure is prevented, side wall shapes of a via hole or a trench used in a (dual) Damascene wiring are controlled in precise manners, and filling of a wiring material into the via hole or the trench is made easily, thereby high reliability is attained.

The present inventor has found that changes in side wall shapes of a via hole or a trench in a Damascene wiring, that occur in the process of etching and removing an insulation barrier layer or an etching stopper layer on a lower layer wiring, in the case when a Damascene wiring structure using a porous low dielectric constant film as an interlayer insulation film is formed, are caused by the fact that the dimensions of hallow holes in the side walls of the via hole or the trench of the porous low dielectric constant film increases in the above etching removal process, and partial contraction of the low dielectric constant film occurs. The present invention has been made on the basis of this new knowledge.

Namely, in order to solve the above problems, a first aspect of the present invention concerning a method of manufacturing a semiconductor device is a method comprising the steps of: forming a lower-layer wiring layer via an insulation film, on a semiconductor substrate having elements formed thereon; forming a first insulation film on the lower-layer wiring layer; forming a second insulation film made of a porous insulation material on the first insulation film; forming a third insulation film on the second insulation film; forming a resist mask having a predetermined opening pattern on the third insulation film; carrying out a first dry etching with the resist mask as an etching mask and forming an opening leading to the first insulation film in the third insulation film and the second insulation film; removing the resist mask, after removing the resist mask, accumulating a barrier metal film on the entire surface so as to cover side walls of the opening; carrying out a second dry etching and etching and removing the barrier metal film accumulated on the first insulation film at the bottom of the opening; carrying out a third dry etching with the third insulation film and the barrier metal film for covering the side walls of the opening as etching masks onto the first insulation film at the lower portion of the opening and letting the opening go through to the lower-layer wiring layer; and filling a conductive material in the opening going through to the lower-layer wiring layer and forming a via plug or an upper-layer wiring layer that connects to the lower-layer wiring layer.

Further, a second aspect of the present invention concerning a method of manufacturing a semiconductor device is a method comprising the steps of: forming a lower-layer wiring layer via an insulation film, on a semiconductor substrate having elements formed thereon; forming a first insulation film on the lower-layer wiring layer; forming a second insulation film made of a porous insulation material on the first insulation film; forming a third insulation film on the second insulation film; forming a fourth insulation film on the third insulation film; forming a resist mask having a predetermined opening pattern on the fourth insulation film; carrying out a first dry etching with the resist mask as an etching mask and transferring the opening pattern to the fourth insulation film; removing the resist mask; carrying out a second dry etching with the fourth insulation film having the opening pattern as an etching mask and forming an opening leading to the first insulation film in the third insulation film and the second insulation film; accumulating a barrier metal film on the entire surface so as to cover side walls of the opening; carrying out a third dry etching and etching and removing the barrier metal film accumulated on the first insulation film at the bottom of the opening; carrying out a fourth dry etching with the fourth insulation film or the third insulation film and the barrier metal film for covering the side walls of the opening as etching masks onto the first insulation film at the lower portion of the opening and letting the opening go through to the lower-layer wiring layer; and filling a conductive material in the opening going through to the lower-layer wiring layer and forming a via plug or an upper-layer wiring layer that connects to the lower-layer wiring layer.

Further, a third aspect of the present invention concerning a method of manufacturing a semiconductor device is a method comprising the steps of: forming a lower-layer wiring layer via an insulation film, on a semiconductor substrate having elements formed thereon; forming a first insulation film on the lower-layer wiring layer; forming a second insulation film made of a porous insulation material on the first insulation film; forming a third insulation film on the second insulation film; forming a fourth insulation film on the third insulation film; forming a first opening pattern in the fourth insulation film by a dry etching using a resist mask and forming a second opening pattern in the third insulation film; removing the resist mask; forming a dual Damascene structure opening leading to the first insulation film in the second insulation film by a dry etching using the fourth insulation film having the first opening pattern and the third insulation film having the second opening pattern as etching masks; accumulating a barrier metal film on the entire surface so as to cover side walls of the dual Damascene structure opening; removing the barrier metal film accumulated on the first insulation film at the bottom of the opening by a dry etching; carrying out a dry etching with the fourth insulation film or the third insulation film and the barrier metal film for covering the side walls of the opening as etching masks onto the first insulation film at the lower portion of the opening and letting the opening go through to the lower-layer wiring layer; and filling a conductive material in the opening going through to the lower-layer wiring layer and forming an upper-layer wiring layer comprising a dual Damascene wiring that connects to the lower-layer wiring layer.

In the above inventions, it is preferred that the barrier metal film comprises a conductive material including a Ta film, a TaN film, a TaSiN film, a WN film, a WSiN film, a TiN film or a TiSiN film.

According to a constitution of the present invention, a porous low dielectric constant film may be applied as an interlayer insulation film between wirings at a practical level, and a semiconductor device with high reliability and high speed actions may be realized.

### BRIEF DESCRIPTION OF THE DRAWINGS

FIG. 1 is a cross sectional view of a Damascene wiring structure of a semiconductor device according to a first embodiment of the present invention;

FIGS. 2A to 2D are cross sectional views of elements in processes illustrating a method of manufacturing the Damascene wiring structure;

FIGS. 3A to 3C are cross sectional views of elements in processes following the processes shown in FIGS. 2A to 2D;

FIGS. 4A to 4C are cross sectional views of elements in processes following the processes shown in FIGS. 3A to 3C;

FIG. 5 is a cross sectional view of a Damascene wiring structure of a semiconductor device according to a second embodiment of the present invention;

FIGS. 6A to 6C are cross sectional views of elements in processes illustrating a method of manufacturing the Damascene wiring structure;

FIGS. 7A to 7C are cross sectional views of elements in processes following the processes shown in FIGS. 6A to 6C;

FIGS. 8A to 8C are cross sectional views of elements in processes following the processes shown in FIGS. 7A to 7C;

FIGS. 9A and 9B are cross sectional views of a Damascene wiring structure of a semiconductor device according to a third embodiment of the present invention;

FIGS. 10A to 10D are cross sectional views of elements in processes illustrating a method of manufacturing a dual Damascene wiring structure according to a prior art; and

FIGS. 11A to 11C are cross sectional views of elements in processes following the processes shown in FIGS. 10A to 10D.

### DESCRIPTION OF THE PREFERRED EMBODIMENTS

As described previously, with respect to elements of a semiconductor device, miniaturization is energetically proceeded toward the dimensional design standard from 65 nm to 45 nm. There is a strong demand for the specific dielectric constant of a low dielectric constant film used in a Damascene wiring being around 2.0 or below. When the specific dielectric constant becomes 2 or below in this way, in an ordinary low dielectric constant film, the porous characteristic thereof becomes further more, and the inclusion ration of hallow holes in the film increases up to near 40%. Herein, the inclusion ratio of hollow holes means the ratio of (Mb−Mp)/Mb, wherein the density of a porous film is defined as Mp, and the density of a bulk (material film not having hollow holes) of the porous film is defined as Mb, about which explanations is made later herein.

However, the conventional side wall protection film or pore seal is configured by an insulation film such as an SiO₂ film or another metal oxide layer whose specific dielectric constant is around 4, which is extremely high in comparison with a low dielectric constant film whose specific dielectric constant is around 2.0 or below. Accordingly, the conventional side wall protection film or pore seal may be applied to a Damascene wiring where a porous low dielectric constant film is used as an interlayer insulation film, but the dielectric constant of the entire interlayer insulation film increases and the parasitic capacity between Damascene wirings increases, and as a result, high performances of a semiconductor device are deteriorated, which has been a problem with the prior art.

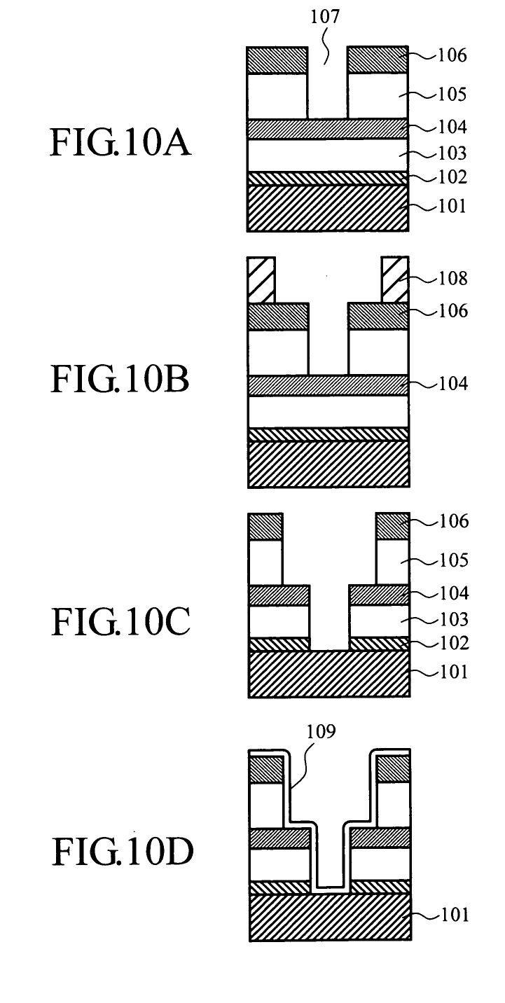

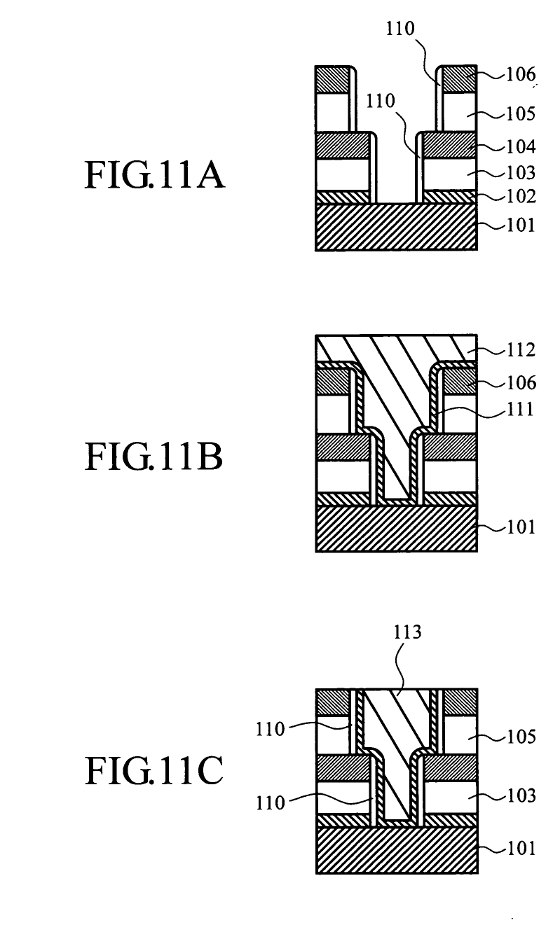

Further, in the conventional example explained previously by reference to FIGS. 10 and 11, the P—SiN film 102 having a function as an insulation barrier to Cu on the lower layer wiring 101 is etched and removed by RIE, and thereafter the third P—SiO₂ film 109 which becomes a pore seal is formed. However, in the etching and removal of an insulation barrier layer or an etching stopper layer on the lower layer wiring 101, if the first low dielectric constant film 103 or the second low dielectric constant film 105 is a porous low dielectric constant film, the side wall shape of a via hole and a trench of the dual Damascene structure of the low dielectric constant film is deteriorated greatly. For example, this side wall shape becomes a barrel (boeing) shape. It becomes difficult to fill a Cu film or a TaN film to become a barrier layer thereof into the via hole and the trench of the dual Damascene structure, which has been another problem with the prior art. This becomes more conspicuous as the dimension of the via hole or the trench becomes smaller.

The present invention has been made in consideration of the above problems with the prior art.

By reference to the attached drawings, the present invention is illustrated in more details by reference to the following referential examples and embodiments.

### First Embodiment

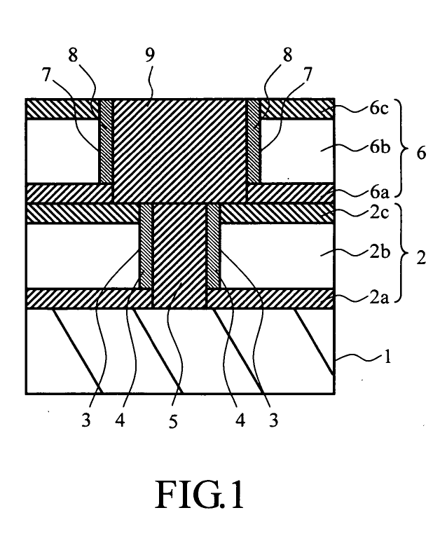

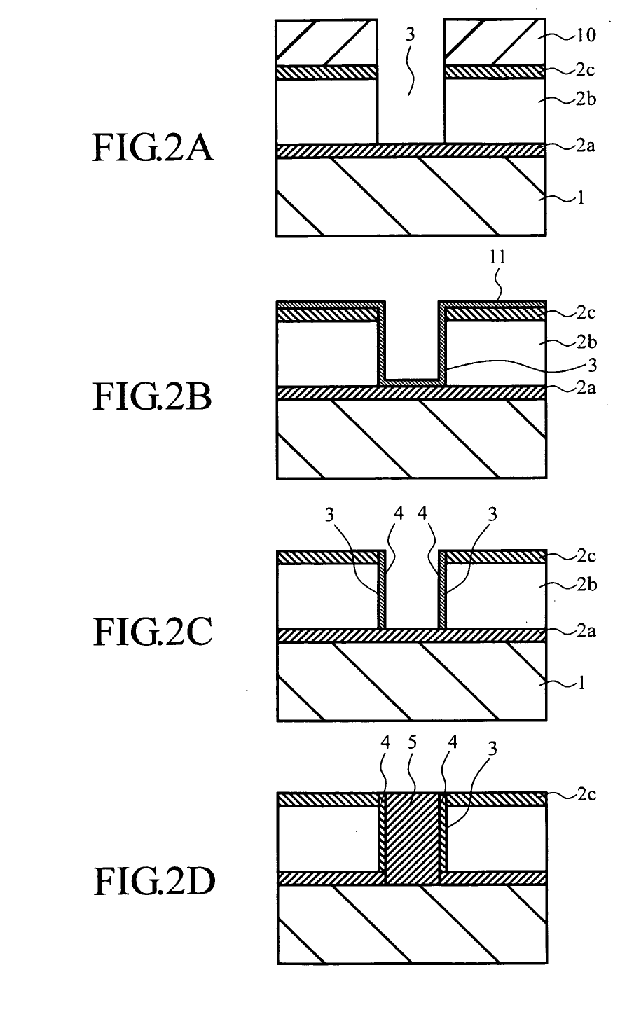

FIG. 1 is a cross sectional view of a Damascene wiring structure of a semiconductor device according to a first embodiment of the present invention, and FIGS. 2 to 4 are cross sectional views of elements in processes illustrating a method of manufacturing the Damascene wiring structure.

As shown in FIG. 1, first, a lower layer wiring 1 of a Damascene wiring structure is formed. Then, in a formation area of a via hole for connecting the lower layer wiring 1 and an upper layer wiring, a via hole 3 that goes through a first interlayer insulation film 2 consisting of a first etching stopper layer 2a as a first insulation film having a function as an insulation barrier, a first low dielectric constant film 2b as a second insulation film, and a first cap layer 2c as a third insulation film is arranged, and a first side wall metal 4 made of a barrier metal is formed on the side walls of the first low dielectric constant film 2b and the first cap layer 2c of the via hole 3. Then, a via plug 5 is arranged so as to fill into the via hole 3. Herein, the via plug 5 is formed with Cu, a Cu alloy, or a metal such as W or the like.

Herein, the first sidewall metal 4 is formed of, for example, a tan tar (Ta) film, a high fusing point metal nitride film such as a tantar nitride (TaN) film, or the like. The film thickness thereof is preferably 2 nm to 10 nm.

Further, the first low dielectric constant film 2b is formed of, for example, a porous methyl silsesquioxane (p-MSQ) film whose specific dielectric constant is around 2.5. It is preferred that the inclusion ratio of hollow holes of the first low dielectric constant film 2b is made 40% or below. This is because when the inclusion ratio goes over 40%, part of hallow holes becomes interconnected, and in the formation of the first side wall metal 4, conductive materials such as TaN are likely to get through these interconnected holes into the first low dielectric constant film 2b. Herein, the inclusion ratio of hallow holes means, as described previously, the ratio of (the density of non porous ultrafine MSQ film bulk)−(the density of porous MSQ film) to (the density of non porous ultrafine MSQ film bulk). The first etching stopper layer 2a is made of a silicon carbide (SiC) film, a nitrogen-containing silicon carbide (SiCN) film or an SiN film, while the first cap layer 2c is made of a carbon-containing silicon oxide (SiOC) film, an SiCN film, an SiN film or an SiO₂ film. However, to the first etching stopper layer 2a and the first cap layer 2c, respectively different insulation films are employed. By the way, the effective specific dielectric constant of the above laminated first interlayer insulation film 2 becomes around 2.5 to 3.0.

In the formation area of the upper layer wiring, a second etching stopper layer 6a as a first insulation film, a second dielectric constant film 6b as a second insulation film, and a second cap layer 6c as a third insulation film are laminated and formed thereby, and onto the inside wall of a trench 7 arranged in a predetermined area of this laminated second interlayer insulation film 6, a second side wall metal 8 made of a barrier metal is arranged. Then, an upper layer wiring 9 made of a Cu film or a Cu alloy film is filled into the trench 7, and formed to be connected to the via plug 5. Herein, the second etching stopper layer 6a, the second low dielectric constant film 6b, and the second cap layer 6c are respectively formed of the same insulation films as the first etching stopper layer 2a, the first low dielectric constant film 2b, and the first cap layer 2c.

Herein, the second side wall metal 8 is formed of a Ta film or a high fusing point metal nitride film in the same manners as the first side wall metal 4. The second low dielectric constant film 6b is formed of a p-MSQ film whose specific dielectric constant is around 2.0, and the effective specific dielectric constant of the second interlayer insulation film 6 is around 2 to 2.5. In this manner, a 2-layer wiring of a Damascene wiring structure is formed. In this Damascene wiring structure, the first cap layer 2c functions as an insulation barrier layer to Cu.

Next, a method of manufacturing the above Damascene wiring structure according to the present invention will be explained in details by reference to FIGS. 2 to 4 hereinafter. Herein, identical codes are allotted to the same components as in FIG. 1.

A silicon oxide film is accumulated on a silicon substrate by a CVD method, and a foundation insulation film (not shown) is formed. Then, a lower layer wiring 1 made of a Cu film is formed by a known Damascene wiring formation method. Then, as a first etching stopper layer 2a as a first insulation film, an SiC film whose film thickness is around 25 nm and whose specific dielectric constant is around 3.5 is formed, and by film formation of a p-MSQ film using a spin-on application method, a first low dielectric constant film 2b as a second insulation film whose specific dielectric constant is around 2.5 and whose film thickness is around 200 nm to 300 nm is formed. Herein, the inclusion ratio of hallow holes of the first low dielectric constant film 2b is around 30%. Then, on the first low dielectric constant film 2b, a first cap layer 2c as a third insulation film made of an SiOC film whose film thickness formed by the CVD method is around 100 nm and whose specific dielectric constant is around 2 to 3 is formed. With a resist mask 10 having an opening pattern of a via hole whose opening diameter is around 100 nm as an etching mask, the above first cap layer 2c and the first low dielectric constant film 2b are dry etched by RIE sequentially, and a via hole 3 whose diameter is around 100 nm is formed. Herein, the first etching stopper layer 2a is left without etching (FIG. 2A) . In the etching of at least the first low dielectric constant film 2b among the above, as an etching gas, for example, fluoro carbon system fluoride compound gas containing much carbon such as C₄F₈ is employed, and an organic polymer that is generated as a reaction product is made as a protection film of via hole side walls. Therefore, in this etching process, there will be no damage on the via hole side walls to be formed.

Next, the above resist mask is removed by plasma of H₂ gas, He gas or the like, then by a PVD method, ALD (atomic layer vapor development) method, CVD method or the like, a first protection metal film 11 is accumulated on the entire surface. Herein, the first protection metal film 11 is, for example, a TaN film. By the film formation of the first protection metal film 11, a TaN film whose film thickness is around 3 nm is formed on the side wall of the via hole 3. Normally, from the relation of step coverage at film formation, the TaN film of a film thickness below that is formed on the first etching stopper layer 2a, while that of a film thickness over that is formed on the first cap layer 2c (FIG. 2B)

In the film formation of this first protection metal film 11, through the hallow holes of the first low dielectric constant film 2b exposed to the side wall of the via hole 3, the metal that composes the first protection metal film 11 will not get into the inside of the first low dielectric constant film 2b. This is because, as explained previously, the inclusion ratio of hallow holes of the first protection metal film 11 at the side wall of the via hole 3 is kept below around 40%, and part of hallow holes is prevented from interconnecting.

Next, an isotropic etch-back is carried out to the first protection metal film 11 by RIE. An etching raw material gas to be used in this etch-back is a mixed gas of chlorine (Cl₂) and hydrogen bromide (HBr), which selectively etches the first protection metal film 11. By this etch-back, the first protection metal film 11 on the first cap layer 2c, and the first protection metal film 11 on the first etching stopper layer 2a are dry etched, and at least the first protection metal film 11 on the first etching stopper layer 2a is etched and removed. On the side wall of the first low dielectric constant film 2b and the first cap layer 2c exposed in the via hole 3, a first side wall metal 4 is formed (FIG. 2C).

By RIE using the etching gas of fluorine compound gas including N₂ gas, with the first cap layer 2c and the first side wall metal 4 as etching masks, the first etching stopper layer 2a is dry etched, and the via hole 3 is made to go through to reach the surface of the lower layer wiring 1. Then, by a known plating method, a Cu film or a Cu alloy film whose film thickness is around 200 nm is formed as a wiring material, and by use of the CMP method, the Cu film and the like of the unnecessary portion on the first cap layer 2c are polished and removed, and a via plug 5 is filled into the via hole 3 and formed therein (FIG. 2D).

Herein, in the dry etching of the above first etching stopper layer 2a as an insulation barrier layer, because the first side wall metal 4 covers the side wall of the via hole 3 of the first low dielectric film 2b, damage owing to the etching gas of fluorine compound gas including N₂ gas, for example, the increase of dimensions of hallow holes and the contraction of the first low dielectric constant film 2b in the via hole 3 that have occurred in the prior art are prevented completely, and there is no cross section shape deformation such as boeing in the via hole 3. There is no interconnection of hallow holes along with the increase of dimensions of hallow holes, and as described previously, metals that structure the first protection metal film 11 do not get into the inside of the first low dielectric constant film 2b, and there is no increase of leak current between wirings.

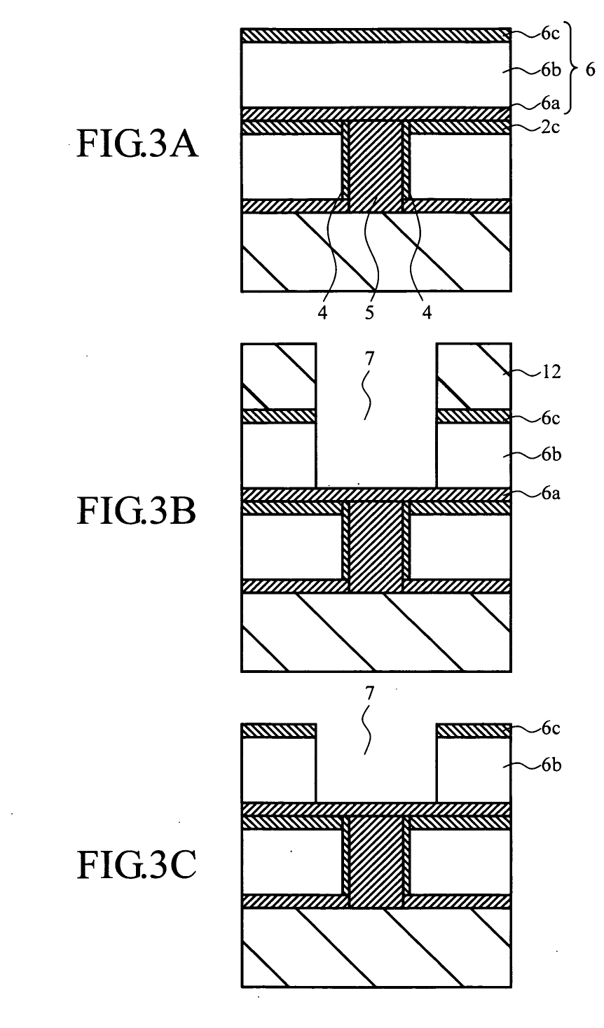

Thereafter, so as to cover the upper portion of the first side wall metal 4 and the via plug 5, a second etching stopper layer 6a as a first insulation film consisting of an SiC film whose film thickness is around 25 nm, and a second low dielectric constant film 6b as a second insulation film consisting of a p-MSQ film whose specific dielectric constant is around 2.0 and whose film thickness is around 200 nm to 300 nm are formed onto the entire surface. Then, on the surface of the second low dielectric constant film 6b, a second cap layer 6c as a third insulation film consisting of an SiOC film whose film thickness is, for example, 100 nm is formed (FIG. 3A).

Then, with a resist mask 12 having an opening pattern of a trench 7 as an etching mask, the second cap layer 6c and the second low dielectric constant film 6b are dry etched by RIE sequentially and the trench 7 whose width dimension is around 150 nm is formed. Herein, the second etching stopper layer 6a is not etched (FIG. 3B). In the etching of at least the second low dielectric constant film 6b among the above too, fluoro carbon system fluorine compound gas including much of carbon such as, for example, C₅F₈ is used as an etching gas, and an organic polymer is generated as a reaction product to protect the side wall of the trench 7. In this manner, in this etching process, there is no damage on the side wall of the via hole to be formed.

Next, in the same manner as explained with FIG. 2A, the resist mask 12 is removed by plasma, and a cleaning process to remove remaining refuse is carried out, and the trench 7 is formed on the second cap layer 6c and the second low dielectric constant film 6b (FIG. 3C).

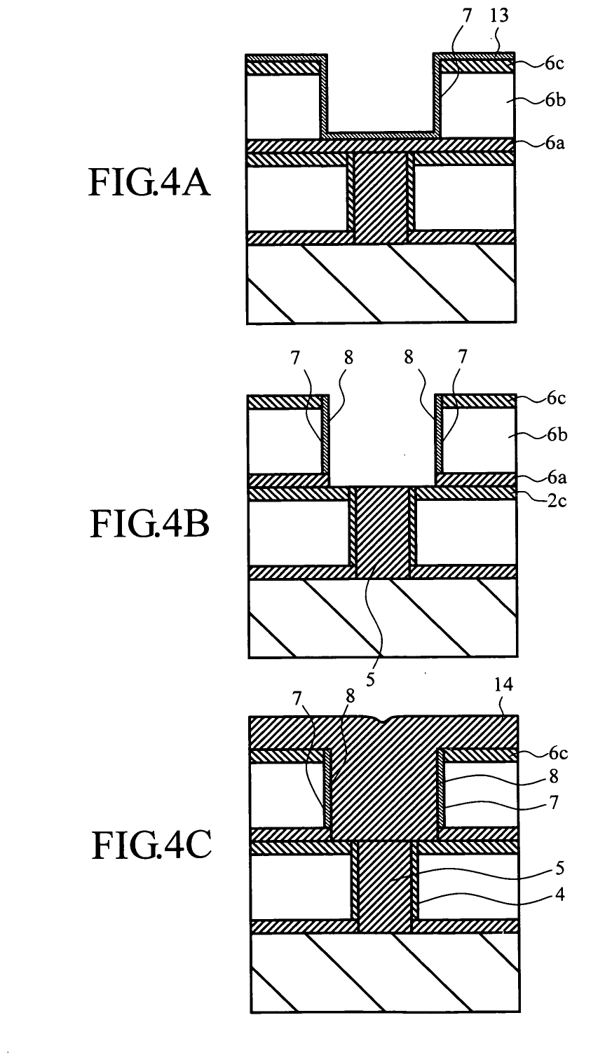

Next, by the PVD method or the like, the second metal film 13 is accumulated on the entire surface. Herein, the second protection metal film 13 is, for example, a TaN film. In the film formation of the second protection metal film 13, a TaN film of a film thickness around 5 nm is formed on the side wall of the second low dielectric constant film 6b of the trench 7. The TaN film of a film thickness below that is formed on the second etching stopper layer 6a, while that of a film thickness over that is formed on the second cap layer 6c (FIG. 4A).

Next, highly anisotropic etch-back is carried out to the second protection metal film 13 by RIE. An etching raw material gas to be used in this etch-back is a mixed gas of (Cl₂) and HBr in the same manner as described previously, which selectively etches the second protection metal film 13. By this etch-back, the second protection metal film 13 on the second cap layer 6c, and the second protection metal film 13 on the second etching stopper layer 6a are dry etched, and at least the second protection metal film 13 on the second etching stopper layer 6a is etched and removed. On the side wall of the second low dielectric constant film 6b and the second cap layer 6c exposed in the trench 7, a second side wall metal 8 of a film thickness around 5 nm is formed (FIG. 4B).

By RIE using the etching gas of fluorine compound gas including N₂ gas, with the second cap layer 6c and the second side wall metal 8 as etching masks, the second etching stopper layer 6a is dry etched, and the trench 7 is made to go through to reach the via plug 5. Then, by a known plating method, a wiring material film 14 consisting of a Cu film or a Cu alloy film whose film thickness is around 500 nm to 110 nm is formed (FIG. 4C). Herein, the wiring material film 14 is connected to the via plug 5. By use of the CMP method, the Cu film and the like on unnecessary portions on the second cap layer 6c are polished and remove. In this manner, the upper layer wiring 9 explained in FIG. 1 is formed, and a 2-layer wiring of a Damascene wiring structure is formed.

In the dry etching of the above second etching stopper layer 6a as an insulation barrier layer, because the second side wall metal 8 covers the side wall of the trench 7 of the second low dielectric film 6b, damage owing to the etching gas of fluorine compound gas including N₂ gas, for example, the increase of dimensions of hallow holes and the contraction of the second low dielectric constant film 6b in the trench 7 that have occurred in the prior art are prevented completely, and there is no cross section shape deformation such as boeing in the trench 7. There is no interconnection of hallow holes along with the increase of dimensions of hallow holes, and as described previously, metals that structure the second protection metal film 13 do not get into the inside of the second low dielectric constant film 6b, and there is no increase of leak current between wirings.

In the formation of a Damascene wiring including Cu, in the dry etching of an insulation barrier layer (etching stopper layer) that is formed on the wiring so as to prevent Cu from diffusing, etching gas including a small content of carbon such as CF₄ is employed as fluorine compound gas. This is because, if fluoro carbon gas including much of carbon as described previously is employed, a large amount of the organic polymer as a reaction product attaches to the wiring surface, it becomes difficult to carry out the dry etching of the above insulation barrier layer. However, the above etching gas of the above insulation barrier layer, in comparison with fluoro carbon system gas including a large amount of carbon mentioned previously, will cause etching damage to a porous low dielectric constant film. Therefore, in the above embodiment, the first side wall metal 4 or the second side wall metal 8 has a function to prevent this etching damage.

Further, in the above embodiment, the inclusion ratio of hallow holes of the first low dielectric constant film 2b or the second low dielectric constant film 7b of a porous structure structuring an interlayer insulation film is preferably 30 to 40%. When the inclusion ratio of hallow holes exceeds 40%, as described previously, hallow holes in the first low dielectric constant film 2b, the second low dielectric constant film 6b interconnect, and metals structuring the first side wall metal 4 or the second side wall metal 9 are likely to get in, and the leak current between wirings increases. Meanwhile, when the inclusion ratio of hallow holes goes below 30%, it becomes extremely difficult to make the specific dielectric constant around 2 or below.

In the first embodiment, while protecting the side wall of the via hole 3 to be arranged on the first interlayer insulation film 2 including the porous first low dielectric constant film 2b against etching damage by the first side wall metal 4, the first etching stopper layer 2a as an insulation barrier layer is etched and removed. Or, while protecting the side wall of the trench to be arranged in the second interlayer insulation film 7 including the porous second low dielectric constant film 7b against etching by the second side wall metal 9, the second etching stopper layer 7a is etched and removed. Therefore, there will be no shape deformation of the side walls of the via hole and the trench of the Damascene structure that has occurred in the prior art, and it is possible to form an ultrafine Damascene wiring structure in a semiconductor device.

Further, the first side wall metal 4 and the second side wall metal 9 are conductive materials, and are electrically connected to the via plug 5 and the upper layer wiring 9 respectively. Accordingly, there will be no increase of the dielectric constant of the first interlayer insulation film 2 or the second interlayer insulation film 7 as in the side wall made of an insulation material in the prior art.

By the first side wall metal 4 and the second side wall metal 9 made of a barrier metal as described previously, the side walls of the via hole and the trench of the Damascene structure are protected, and therefore, cracks arising from the decrease of mechanical strength of interlayer insulation films including porous low dielectric constant films and short-circuit failures between wirings are reduced greatly. Further, the above first side wall metal 4 and the second side wall metal 9 can completely prevent water content or Cu of the wiring material film from getting into the inside of the interlayer insulation films. Accordingly, the interlayer insulation films of the Damascene wiring structure will have high reliability, and there will be no increase of effective dielectric constant of the interlayer insulation films, and further, there will be no problem such as disconnection/incomplete connection or the like at the via portion owing to the increase of the leak current between wirings and the intrusion of the above Cu into porous low dielectric constant films.

Further, it becomes easy to make multiple layers of a Damascene wiring in a semiconductor device. It becomes possible to form a highly reliable and ultrafine Damascene wiring structure in a semiconductor device at a practical level. In this manner, a semiconductor device with high reliability and high speed actions is realized.

### Second Embodiment

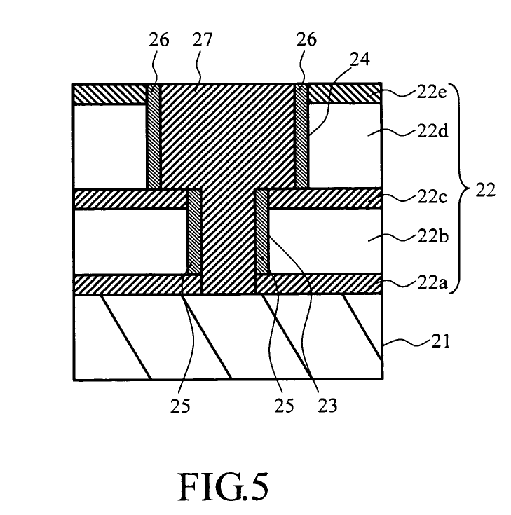

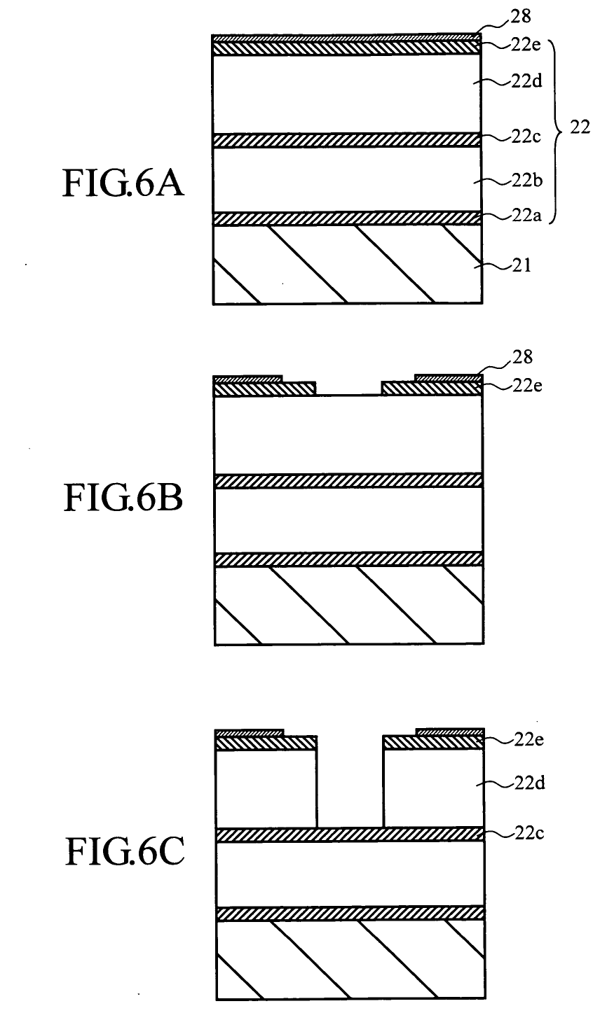

Next, a second embodiment of the present invention will be explained by reference to FIGS. 5 to 8 hereinafter. The characteristic of this case is that the present invention is applied to the formation of a dual Damascene wiring. Herein, FIG. 5 is a cross sectional view of a dual Damascene wiring structure where a via plug and a Damascene wiring are formed integrally as an upper layer wiring, and FIGS. 6 to 8 are cross sectional views of elements of the dual Damascene wiring structure in processes.

As shown in FIG. 5, a lower layer wiring 21 made of, for example, aluminum copper alloy is formed. In a formation area of a dual Damascene wiring that connects to a lower layer wiring 21, in an interlayer insulation film 22 consisting of a laminated film of an etching stopper layer 22a, a first low dielectric constant film 22b, a mid stopper layer 22c, a second low dielectric constant film 22d and a cap layer 22e, a via hole 23 and a trench 24 of a dual Damascene structure are arranged, and to the first low dielectric constant film 22b of the via hole 23 and the side wall of the mid stopper layer 22c, a via portion side wall metal 25 is formed. Then, in the same manner, to the side walls of the second low dielectric constant film 22d and the cap layer 22e of the trench 24, a trench portion side wall metal 26 is arranged. An upper layer wiring 27 of a dual Damascene structure is filled into the via hole 23 and the trench 24 of the dual Damascene structure, and arranged so as to electrically connected directly to the lower layer wiring 21.

Herein, the via portion side wall metal 25 and the trench portion side wall metal 26 are made of a Ta film or a high fusing point metal nitride film formed by, for example, an ALD method, CVD method or the like, and the film thickness thereof is 2 nm to 10 nm.

The first dielectric constant film 22b and the second low dielectric constant film 22d are a porous p-MSQ film whose specific dielectric constant is around 1.8, and the etching stopper layer 22a is, for example, an SiC film, while the mid stopper layer 22c and the cap layer 22e are formed of, for example, an SiOC film. By the way, the effective specific dielectric constant of the above laminated interlayer insulation film 22 is around 2 to 2.5. In this dual Damascene wiring structure, it is preferred that the mid stopper layer 22c functions as an insulation barrier layer to Cu.

Next, a method of manufacturing the above dual Damascene wiring structure according to the present invention will be explained in details by reference to FIGS. 6 to 8 hereinafter. Herein, identical codes are allotted to the same components as in FIG. 5.

A silicon oxide film is accumulated on a silicon substrate by the CVD method, and a foundation insulation film (not shown) is formed. Then, a lower layer wiring 21 is formed by a known aluminum copper alloy film formation method and the process thereof. Then, as an etching stopper layer 22a as a first insulation film, an SiC film whose film thickness is around 25 nm and whose specific dielectric constant is around 3.5 is formed, and by film formation of a p-MSQ film using a spin-on application method, a first low dielectric constant film 22b as a second insulation film whose specific dielectric constant is around 1.8 and whose film thickness is around 200 nm to 300 nm is formed. Herein, the inclusion ratio of hallow holes of the first low dielectric constant film 2b is around 40%. Then, on the first low dielectric constant film 22b, a mid stopper layer 22c made of an SiOC film whose film thickness formed by the CVD method is around 100 nm and whose specific dielectric constant is around 2 to 3 is formed. Further, on the mid stopper layer 22c, a second low dielectric constant film 22d as a second insulation film is formed. This second low dielectric constant film 22d is formed in the same manner as the first low dielectric constant film 22b. However, the film thickness thereof is made thicker than that of the first low dielectric constant film 22b. Then, on the second low dielectric constant film 22d, a cap layer 22e as a third insulation film is formed. By these multilayer laminated insulation films, an interlayer insulation film 22 is structured. Herein, the cap layer 22e becomes a first hard mask layer as described later. On this cap layer 22e, a second hard mask layer 28 made of a silicon oxide film whose film thickness is, for example, around 50 nm as a fourth insulation film is formed (FIG. 6A).

Next, by known lithography technology and dry etching technology, by use of respective resist masks, the above second hard mask layer 28 and the cap layer 22e are dry etched, and opening patterns are transferred to them respectively. A hard mask layer 22e having an opening whose diameter is, for example, 80 nm, and a second hard mask 28 having an opening whose width dimension is, for example, 100 nm are formed. Then, by the method explained in the first embodiment, the resist masks are removed (FIG. 6B).

Next, by RIE with the first hardmask layer 22e as an etching mask, the second low dielectric constant film 22d is dry etched, and a via pattern leading to the surface of the mid stopper layer 22c is transferred. Herein, an etching gas to be used includes, for example, a fluorine compound gas of fluoro carbon system described previously (FIG. 6A).

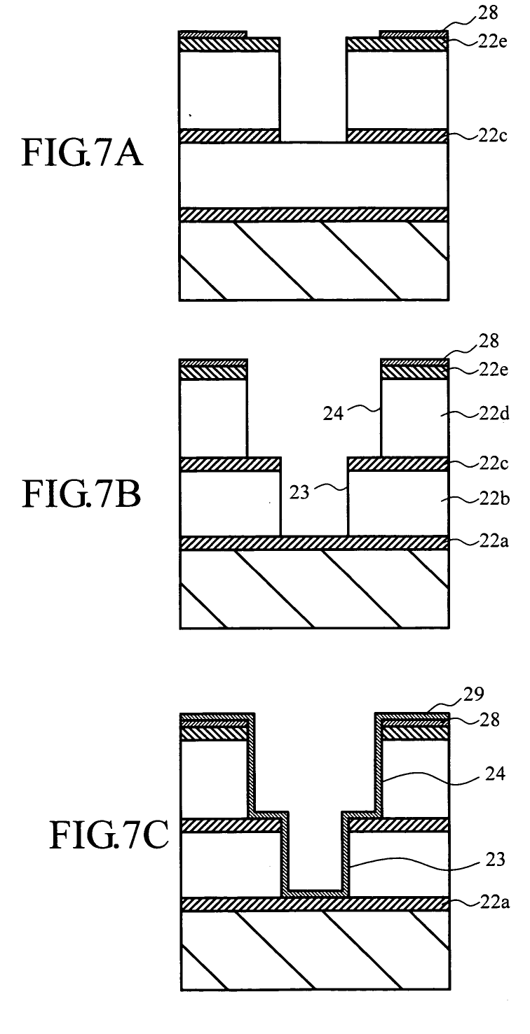

Next, by RIE with the second hardmask layer 28 as an etching mask, the first hard mask layer 22e is dry etched, and the trench pattern of the second hard mask layer 28 is transferred to the first hard mask layer 22e. At the same time, the mid stopper layer 22c is etched and a via pattern is transferred. Herein, an etching gas to be used includes, for example, a fluorine compound gas of hydro fluoro carbon system such as CH₂F₂ (FIG. 7A).

Thereafter, with the first hardmask layer 28 as an etching mask, the second low dielectric constant film 22d is etched, and a trench pattern is transferred to the second low dielectric constant film 22d. At the same time, with the mid stopper layer 22 as an etching mask, the first low dielectric constant film 22b is etched, and a via pattern is transferred to the first low dielectric constant film 22b. The etching gas to be used herein includes a fluorine compound gas of fluoro carbon system including much of carbon from the same reason in the first embodiment. In this manner, a via hole 23 to become a dual Damascene structure is formed on the first low dielectric constant film 22b and the mid stopper layer 22c, and a trench 24 to become a dual Damascene structure as well is formed on the second low dielectric constant film 22d and the cap layer 22e. Herein, the etching stopper layer 22a is not etched (FIG. 7B).

Next, by the ALD method, CVD method or the like, a protection metal layer 29 is formed on the entire surface, and onto the exposed etching stopper layer 22a, the via hole 23 side wall, the trench 24 side wall and the second hard mask 28 surface, the protection metal film 29 is accumulated. Herein, the protection metal film 29 is a conductive barrier film to Cu, and is a high fusing point metal nitride film with a film thickness around 2 nm to 10 nm such as a Ta film or a TaN film (FIG. 7C)

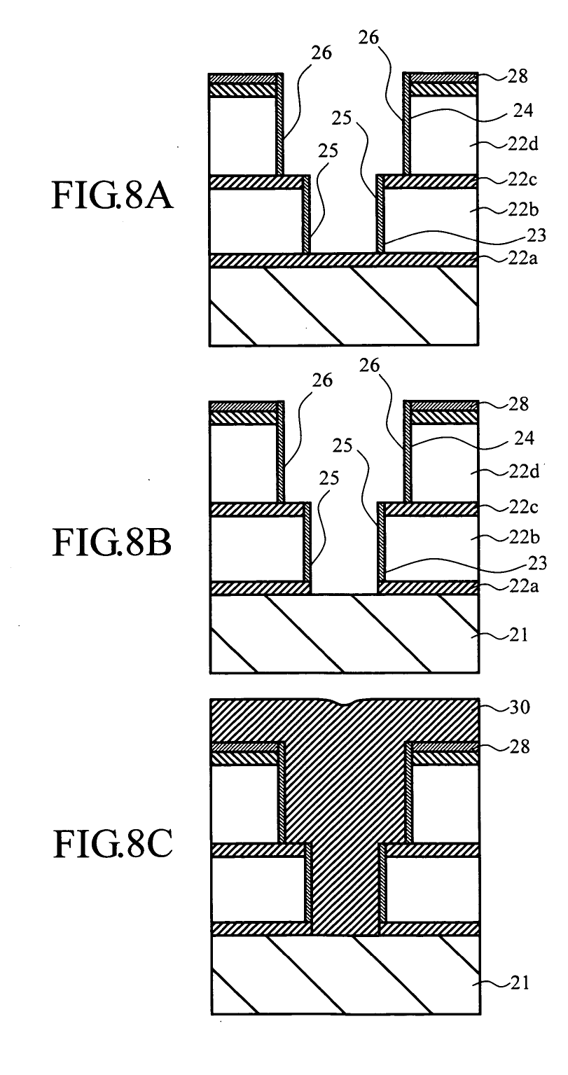

Next, in the same manner as explained in the first embodiment, highly anisotropic etch-back is carried out by RIE. By this etch-back, the protection metal film 29 on the second hard mask 28 and on the etching stopper layer 22a is etched and removed, and a via portion side wall metal 25 is formed on the side wall of the first low dielectric constant film 22b exposed in the via hole 23, and a trench portion side wall metal 26 is formed on the side wall of the second low dielectric constant film 22d exposed in the trench 24 (FIG. 8A).

Next, by RIE using the etching gas of fluorine compound gas including N₂ gas, with the second hard mask 28, the mid stopper layer 22c, the via portion side wall metal 25 and the trench portion side wall metal 26 as etching masks, the etching stopper layer 22a is dry etched, and the via hole 23 is made to go through to the surface of the lower layer wiring 21 (FIG. 8B).

In the dry etching of the above etching stopper layer 22a as an insulation barrier layer, because the via portion side wall metal 25 and the trench portion side wall metal 26 respectively cover the first low dielectric constant film 22b side wall and the second low dielectric constant film 22d side wall, as described in the first embodiment, damage owing to the etching gas is prevented, there is no cross section shape deformation such as boeing in the via hole 23 and the trench 24 of the dual Damascene structure. There is no interconnection of hallow holes along with the increase of dimensions of hallow holes, and as described previously, metals that structure the protection metal film 29 do not get into the inside of the first low dielectric constant film 22 or the second low dielectric constant film 22d, and there is no increase of leak current between wirings.

Next, a Cu film whose film thickness is around 500 nm to 1 μm is accumulated by use of a plating method or the like, and thereby a wiring material film 30 is formed (FIG. 8C) . By use of the CMP method, the Cu film and the above second hard mask layer 28 on unnecessary portions on the second hard mask layer 28 are polished and remove. In this manner, the upper layer wiring 27 explained in FIG. 5 is formed, and a 2-layer wiring of a dual Damascene wiring structure is formed.

In the above second embodiment, quite the same effects as explained in the first embodiment are attained. Further, in this case, the method of manufacturing a Damascene wiring structure becomes simpler than in the first embodiment. Further, part of other insulation layers than porous low dielectric constant films to be inserted into interlayer insulation films (etching stopper layer or cap layer) maybe omitted, and therefore it becomes possible to further decrease the effective dielectric constant of interlayer insulation films. Accordingly, actions of a semiconductor device is made at a further higher speed.

### Third Embodiment

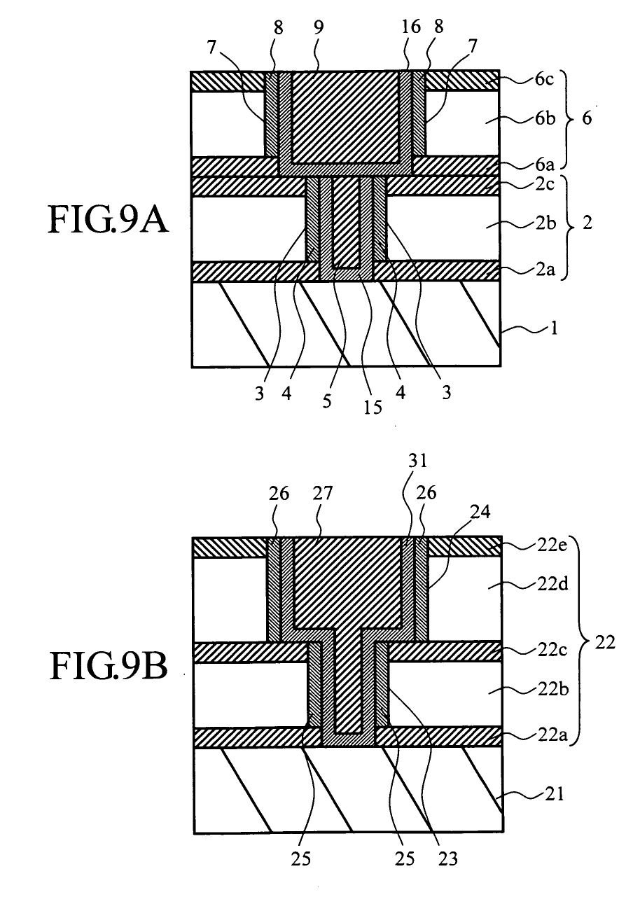

Next, a third embodiment of the present invention will be explained by reference to FIGS. 9A and 9B hereinafter. The characteristic of this case is that, in the first and second embodiments, further a conductive barrier layer is formed in a via hole or a trench of a Damascene structure, Herein, FIG. 9A is a cross sectional view of a Damascene wiring structure where the above conductive barrier layer is formed in the first embodiment, while FIG. 9B is across sectional view of a Damascene wiring structure where the above conductive barrier layer is formed in the second embodiment. Herein, identical codes are allotted to the same components as in FIGS. 1 and 5, and explanations for part thereof are omitted.

As shown in FIG. 9A, a first side wall metal 4 is formed on the side wall of a via hole 3 arranged in a first interlayer insulation film 2, further a first barrier layer 15 that covers the first side wall metal 4 and connects to a lower layer wiring 1 is formed, and a via plug 5 is arranged so as to fill the via hole 3 through the first barrier layer 15. Herein, the first barrier layer 15 is formed of a conductive barrier film such as a tungsten nitride (WN) film whose film thickness is 1 nm to 5 nm, and prevents diffusion of Cu. Then, a second side wall metal 8 is formed on the side wall of a trench 7 arranged in a second interlayer insulation film 6, further a second barrier layer 16 that covers the second side wall metal 8 and connects to the above via plug 5, and an upper layer wiring 9 is arranged so as to fill the trench 7 through the second barrier layer 16. Herein, the second barrier layer 16 is formed of a conductive barrier film such as a WN film whose film thickness is around 5 nm.

Further, in the dual Damascene wiring structure, as shown in FIG. 9B, to the side walls of a via hole 23 and a trench 24 of a dual Damascene structure formed in an interlayer insulation film 22, a via portion side wall metal 35 and a trench portion side wall metal 26 are respectively formed, further a barrier layer 31 that covers the via portion side wall metal 25 and the trench portion side wall metal 26 and connects to a lower layer wiring 21 is formed. An upper layer wiring 27 of a dual Damascene structure made of a Cu film is arranged so as to fill the via hole 23 and the trench 24 through the barrier layer 31. Herein, the barrier layer 31 is formed of a conductive barrier film such as a WN film whose film thickness is 1 nm to 10 nm, and prevents diffusion of Cu.

In this manner, the via plug 5 made of Cu, and the upper layer wirings 9 and 27 are completely covered with the first barrier layer 4, the second barrier layer 8 or the barrier layer 31 as a conductive barrier, and therefore, for example, a first cap layer 2c or a mid stopper layer 22c may be an insulation film that does not have a barrier property against Cu, and the selection range of insulation materials structuring interlayer insulation films such as the first cap 2c or mid stopper layer 22c will be increased greatly, and it becomes easy to reduce the effective dielectric constant of interlayer insulation films.

Heretofore, although embodiments of the present invention have been explained, the embodiment mentioned above do not limit the present invention. It may be well understood by those skilled in the art that the present invention may be embodied in other specific forms without departing from the spirit or essential characteristics thereof.

For example, in the above embodiments, between the side wall metal formed on the side wall of the via hole or the trench and the low dielectric constant film structuring the interlayer insulation film, the following porous protection insulation film may be arranged. Namely, this porous protection insulation film is a porous insulation film of the same kind as or a different kind from the above first and second low dielectric constant films. Herein, it is preferred that the inclusion ratio of hallow holes in the porous insulation film is 30% or below, and the dimension of the hallow holes is 2 nm or below. In this manner, even if the porous degree of the first low dielectric constant film 2b or the second low dielectric constant film 6b becomes high, for example, if the inclusion ratio of hallow holes in the film exceeds 40%, hallow holes of the above porous protection insulation film formed on the side wall of the via hole or the trench of the Damascene structure will not interconnect with one another but exist independently. As a result, at the film formation of the first, second protection metal films 11, 13, the protection metal film 29, the component metals thereof are prevented from getting into the first low dielectric constant film 2b or the second low dielectric constant film 6b. It becomes possible to use the first low dielectric constant film 2b or the second low dielectric constant film 6b whose porous degree becomes further higher, and whose specific dielectric constant becomes further as smaller as, for example, around 1.6.

Further, with regard to the sidewall metal, one of a 1-layer structure is employed in the above embodiments, while a 2-layer or more-layer structure may be employed too.

Further, as the low dielectric film of a porous structure according to the present invention, as well as a p-MSQ film, a porous insulation film of another insulation film having a siloxane framework or an insulation film having an organic polymer as its main framework may be employed. By the way, as an insulation film having the siloxane framework, there is a silica film including at least one of Si—CH₃ combination, Si—H combination, and Si—F combination as an insulation film of silsesquioxane group, and as an insulation film having an organic polymer as its main framework, there is an SiLK (registered trademark) made of an organic polymer. As well known insulation materials as an insulation film of silsesquioxane group, there are, besides the above MSQ, hydrogen silsesquioxane (HSQ), methylated hydrogen silsesquioxane (MHSQ) and so forth. Further, as the low dielectric constant film of a porous structure, a porous SiOH film, and SiOC film formed by CVD method may be employed as well.

Further, in the above embodiments, as each etching stopper layer, an SiC film, an SiCN film, an SiOC film, an SiN film or a laminated film of them may be employed as well. As each cap layer, an SiOC film, an SiCN film, an SiN film, an SiO₂ film or a laminated film of them may be employed as well. However, it is preferred to use respectively different insulation films to the above etching stopper layer and the cap layer.

Furthermore, as the conductive material film of the side wall of the barrier metal, besides the above, as ones including a high fusing point metal nitride film, a TaSiN film, a WN film, a WSiN film, a TiN film, and a TiSiN film may be used. Or, a conductive composite film consisting of laminated films with high fusing point metal films such as Ta, W, and Ti or a conductive composite film consisting of laminated films of the above high fusing point metal nitride film may be employed as well.

1-15. (canceled)

16. A method of manufacturing a semiconductor device, comprising the steps of:
forming a lower-layer wiring layer via an insulation film, on a semiconductor substrate having elements formed thereon;
forming a first insulation film on the lower-layer wiring layer;
forming an interlayer insulation film including a film made of a porous insulation material on the first insulation film;
forming an opening leading to the first insulation film in the interlayer insulation film by carrying out a dry etching with a mask having a predetermined opening pattern;
accumulating a barrier metal film on the entire surface so as to cover side walls of the opening;
removing the barrier metal film accumulated on the first insulation film at the bottom of the opening by carrying out a dry etching;
removing the first insulation film at the lower portion of the opening by carrying out a dry etching with the interlayer insulation film and the barrier metal film for covering the side walls of the opening as etching masks and whereby the opening extends through to the lower-layer wiring layer; and
filling a conductive material in the opening and forming a conductive layer.

17. The method of manufacturing a semiconductor device according to claim 16, wherein
the step of forming the interlayer insulation film includes steps of forming a second insulation film made of the porous insulation material on the first insulation film and forming a third insulation film on the second insulation film,
the step of forming the opening leading to the first insulation film includes steps of forming a resist mask having the predetermined opening pattern on the third insulation film to carry out the dry etching with the resist mask in the third insulation film and the second insulation film and removing the resist mask,
the step of accumulating the barrier metal film is performed after the step of removing the resist mask,
in the step of removing the first insulation film, the dry etching is carried out with the third insulation film and the barrier metal film for covering the side walls of the opening as the etching masks onto the first insulation film at the lower portion of the opening whereby the opening extends through to the lower-layer wiring layer, and
in the step of filling the conductive material, a via plug or an upper-layer wiring layer that connects to the lower-layer wiring layer is formed.

18. The method of manufacturing a semiconductor device according to claim 17, wherein the porous insulation film is formed of a low dielectric constant material.

19. The method of manufacturing a semiconductor device according to claim 17, wherein the first insulation film is a thin film made of SiC, SiOC, SiCN or SiN.

20. The method of manufacturing a semiconductor device according to claim 18, wherein the first insulation film is a thin film made of SiC.

21. The method of manufacturing a semiconductor device according to claim 17, wherein the second insulation film is a porous thin film made of MSQ.

22. The method of manufacturing a semiconductor device according to claim 17, wherein the barrier metal film comprises a conductive material including a Ta film, a TaN film, a TaSiN film, a WN film, a WSiN film, a TiN film or a TiSiN film.

23. The method of manufacturing a semiconductor device according to claim 16, wherein the step of forming the interlayer insulation film includes steps of
forming a second insulation film made of the porous insulation material on the first insulation film,
forming a third insulation film on the second insulation film, and
forming a fourth insulation film on the third insulation film,
the step of forming the opening leading to the first insulation film includes steps of forming a resist mask having the predetermined opening pattern on the fourth insulation film to carry out the dry etching with the resist mask as an etching mask and transferring the opening pattern to the fourth insulation film,
removing the resist mask, and
carrying out a second dry etching with the fourth insulation film having the opening pattern as an etching mask and forming an opening leading to the first insulation film in the third insulation film and the second insulation film,
in the step of removing the first insulation film, the dry etching is carried out with the fourth insulation film or the third insulation film and the barrier metal film for covering the side walls of the opening as etching masks onto the first insulation film at the lower portion of the opening whereby the opening extends through to the lower-layer wiring layer, and
in the step of filling the conductive material, a via plug or an upper-layer wiring layer that connects to the lower-layer wiring layer is formed.

24. The method of manufacturing a semiconductor device according to claim 23, wherein the porous insulation film is formed of a low dielectric constant material.

25. The method of manufacturing a semiconductor device according to claim 23, wherein the first insulation film is a thin film made of SiC, SiOC, SiCN or SiN.

26. The method of manufacturing a semiconductor device according to claim 25, wherein the first insulation film is a thin film made of SiC.

27. The method of manufacturing a semiconductor device according to claim 23, wherein the second and the fourth insulation films are porous thin films made of MSQ.

28. The method of manufacturing a semiconductor device according to claim 23, wherein the barrier metal film comprises a conductive material including a Ta film, a TaN film, a TaSiN film, a WN film, a WSiN film, a TiN film or a TiSiN film.

29. The method of manufacturing a semiconductor device according to claim 16, wherein the step of forming the interlayer insulation film includes steps of
forming a second insulation film made of the porous insulation material on the first insulation film,
forming a third insulation film on the second insulation film, and
forming a fourth insulation film on the third insulation film,
the step of forming the opening leading to the first insulation film includes steps of forming a first opening pattern in the fourth insulation film by a dry etching using a resist mask and forming a second opening pattern in the third insulation film,
removing the resist mask,
forming a dual Damascene structure opening leading to the first insulation film in the second insulation film by a dry etching using the fourth insulation film having the first opening pattern and the third insulation film having the second opening pattern as etching masks, and
in the step of accumulating the barrier metal film, the barrier metal film is formed on the entire surface so as to cover side walls of the dual Damascene structure opening,
in the step of removing the first insulation film, the dry etching is carried out with the fourth insulation film or the third insulation film and the barrier metal film for covering the side walls of the opening as etching masks onto the first insulation film at the lower portion of the opening whereby the opening extends through to the lower-layer wiring layer, and
in the step of filling the conductive material, an upper-layer wiring layer comprising a dual Damascene wiring that connects to the lower-layer wiring layer is formed.

30. The method of manufacturing a semiconductor device according to claim 29, wherein the porous insulation film is formed of a low dielectric constant material.

31. The method of manufacturing a semiconductor device according to claim 29, wherein the barrier metal film comprises a conductive material including a Ta film, a TaN film, a TaSiN film, a WN film, a WSiN film, a TiN film or a TiSiN film.
